(19) United States
(12) Patent Application Publication
(10) Pub. No.: US 2022/0148858 A1
(43) Pub. Date: May 12, 2022

(54) SUBSTRATE PROCESSING SYSTEM

(71) Applicant: TOKYO ELECTRON LIMITED, Tokyo (JP)

(72) Inventors: Daisuke Hayashi, Yamanashi (JP); Norihiko Amikura, Miyagi (JP)

(73) Assignee: TOKYO ELECTRON LIMITED, Tokyo (JP)

(21) Appl. No.: 17/522,609

(22) Filed: Nov. 9, 2021

(30) Foreign Application Priority Data
Nov. 9, 2020 (JP) 2020-186622
Oct. 14, 2021 (JP) 2021-168636

(51) Int. Cl. H01J 37/32; H01L 21/677

(52) U.S. Cl. CPC H01J 37/32651; H01L 21/67742; H01J 37/32477; H01J 37/32899

(57) ABSTRACT

A substrate processing system is disclosed. The system comprises a first chamber having a first substrate transfer port; a second chamber having a second substrate transfer port and configured to perform substrate processing; a connecting member that allows the first substrate transfer port and the second substrate transfer port to communicate with each other; a heat shield portion disposed along the second transfer port in cross-sectional view and configured to thermally block the first chamber and the second chamber from each other; and a protective member disposed between the heat shield portion and the second transfer port and configured to prevent deterioration of the heat shield portion during substrate processing in the second chamber.

### CROSS-REFERENCE TO RELATED APPLICATIONS

This application claims priority to Japanese Patent Application Nos. 2020-186622 filed on Nov. 9, 2020 and 2021-168636 filed on Oct. 14, 2021, respectively, the entire contents of which are incorporated herein by reference.

### TECHNICAL FIELD

The present disclosure relates to a substrate processing system.

### Background

Japanese Patent Application Publication No. 2014-214863 discloses a gate valve for opening and closing an opening that connects a processing chamber and a transfer chamber. The gate valve forms a gap that is curved to prevent radicals in the processing chamber from reaching a sealing member of the gate valve when the opening is closed.

### Summary

The technique of the present disclosure appropriately shields heat between a first substrate processing chamber and a second substrate processing chamber disposed adjacent to each other using a heat shield member, and appropriately suppresses deterioration of the heat shield member during substrate processing.

One aspect of the present disclosure relates to a substrate processing system comprising: a first chamber having a first substrate transfer port; a second chamber having a second substrate transfer port and configured to perform substrate processing; a connecting member that allows the first substrate transfer port and the second substrate transfer port to communicate with each other; a heat shield portion disposed along the second transfer port in cross-sectional view and configured to thermally block the first chamber and the second chamber from each other; and a protective member disposed between the heat shield portion and the second transfer port and configured to prevent deterioration of the heat shield portion during substrate processing in the second chamber.

### BRIEF DESCRIPTION OF THE DRAWINGS

The objects and features of the present disclosure will become apparent from the following description of embodiments, given in conjunction with the accompanying drawings, in which:

FIG. 1 is a plan view showing a schematic configuration of a wafer processing apparatus according to an embodiment;

FIG. 2A is a side cross-sectional view showing an example of a configuration of a gate module according to an embodiment;

FIG. 2B is a front cross-sectional view showing a cross section along the line IIB-IIB shown in FIG. 2A;

FIG. 3 is an enlarged view of a main part shown in FIG. 2A;

FIG. 4 is a side cross-sectional view showing another configuration example of the gate module;

FIG. 5A is a side cross-sectional view showing still another configuration example of the gate module;

FIG. 5B is a front cross-sectional view showing a cross section along the line VB-VB shown in FIG. 5A;

FIG. 6A is a side cross-sectional view showing yet another configuration example of the gate module;

FIG. 6B is a side cross-sectional view showing still another configuration example of the gate module; and

FIG. 7 is a side cross-sectional view schematically showing another connection example of a processing module.

### DETAILED DESCRIPTION

In a semiconductor device manufacturing process, a processing gas is supplied with respect to a semiconductor wafer (hereinafter, simply referred to as “wafer”) and the wafer is subjected to various plasma processing such as etching, film formation, diffusion, and the like. Such plasma processing is performed in a vacuum processing chamber the inner space of which can be controlled to a depressurized atmosphere. The vacuum processing chamber communicates with a transfer chamber for loading/unloading the wafer to/from the vacuum processing chamber through an opening as a loading/unloading port, and the opening is opened and closed by a gate valve.

Here, when plasma processing is performed in the vacuum processing chamber as described above, a sealing member (e.g., an O-ring) disposed at the gate valve may be deteriorated by radicals generated in the vacuum processing chamber. Therefore, in the gate valve, it is necessary to protect the sealing member from the deterioration caused by the radicals.

The above-described Japanese Patent Application Publication No. 2014-214863 discloses a gate valve used for opening and closing a loading/unloading port of a processing chamber (vacuum processing chamber). In accordance with the gate valve disclosed in Japanese Patent Application Publication No. 2014-214863, when the opening serving as the loading/unloading port is closed, a convex wall formed on a valve plate of the gate valve is fitted into the opening to form a narrow gap at the end portion of the opening. Further, the gate valve disclosed in Japanese Patent Application Publication No. 2014-214863 attempts to reduce the amount of radicals reaching the sealing member disposed at the gate valve by using the narrow gap.

In the semiconductor device manufacturing process, however, plasma processing under a high temperature environment (e.g., 100° C. or higher), which is one of the representative post-treatment (e.g., ashing), may be performed. Here, an electrical component that is weak to the high temperature environment, e.g., a positioning sensor or an actuator, is generally used for the gate valve, and, thus, it is required to seek a measure for preventing an increase in the temperature of the electrical component in addition to the above-described problem caused by radicals.

In order to prevent the temperature increase in the electrical component, it is possible to connect the vacuum processing chamber and the transfer chamber by using, as an adaptor, a heat shield plate (e.g., a resin material or the like) for preventing heat transfer from the vacuum processing chamber to the transfer chamber, for example. However, a high strength heat shield plate (resin material) suitable for the adapter is weak to the deterioration caused by radicals. Therefore, it is necessary to protect the heat shield plate from radicals. Further, when a corrosive gas is used for plasma processing, for example, the heat shield plate may be deteriorated by the corrosive gas and, thus, it is necessary to protect the heat shield plate from the corrosive gas.

Japanese Patent Application Publication No. 2014-214863 does not disclose a solution to both of the problem caused by the radicals or the corrosive gas and the problem of the high temperature in the gate valve. In other words, there is a need to improve a conventional wafer processing system for performing plasma processing on a wafer.

The technique of the present disclosure appropriately shields heat between the first substrate processing chamber and the second substrate processing chamber disposed adjacent to each other by using the heat shield member and, at the same time, appropriately suppresses the deterioration of the heat shield member during the substrate processing. Hereinafter, a wafer processing apparatus as a substrate processing system according to an embodiment and a wafer processing method performed by using the wafer processing apparatus will be described with reference to the drawings. Further, like reference numerals will be given to like parts having substantially the same functions throughout the specification and the drawings, and redundant description thereof will be omitted.

### <Wafer Processing Apparatus>

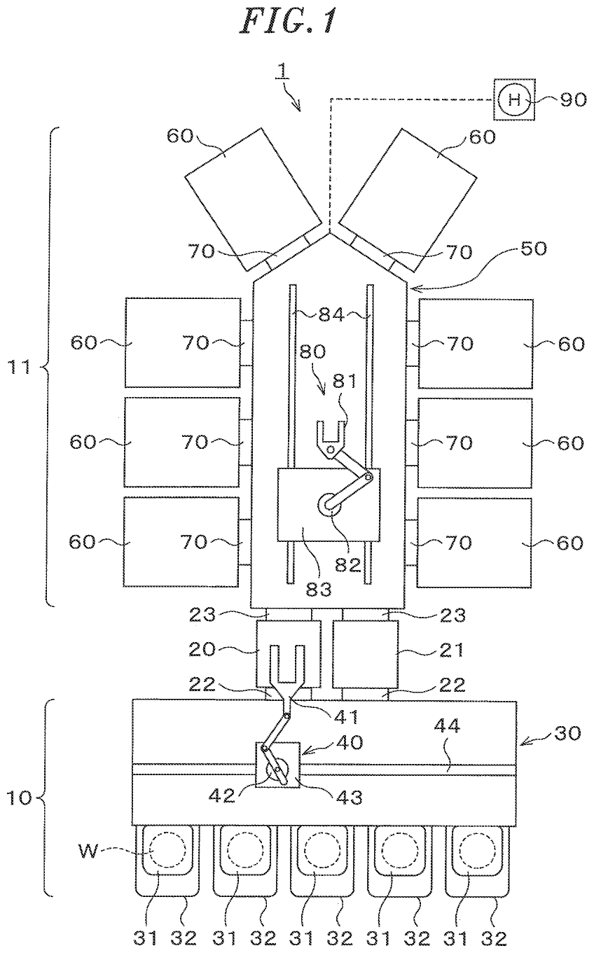

First, a wafer processing apparatus according to an embodiment will be described. FIG. 1 is a plan view showing a schematic configuration of a wafer processing apparatus 1 according to an embodiment. In the following description, a case will be described as an example, where the wafer processing apparatus 1 performs plasma processing related to post-treatment, such as asking or the like, on the wafer W as a substrate and a heat shield portion to be described later is protected from radicals generated during the plasma processing.

As shown in FIG. 1, the wafer processing apparatus 1 has a configuration in which an atmospheric unit 10 and a depressurization unit 11 are integrally connected through load-lock modules 20 and 21. The atmospheric unit 10 includes an atmospheric module for performing desired processing on the wafer W in an atmospheric atmosphere. The depressurization unit 11 includes a depressurization module for performing desired processing on the wafer W in a depressurized atmosphere.

The load-lock modules 20 and 21 are disposed to connect a loader module 30 (to be described later) in the atmospheric unit 10 and a transfer module 50 (to be described later) in the depressurization unit 11 through gate valves 22 and 23. The load-lock modules 20 and 21 are configured to temporarily hold the wafer W. Further, inner atmospheres of the load-lock modules 20 and 21 can be switched between an atmospheric atmosphere and a depressurized atmosphere (vacuum state).

The atmospheric unit 10 includes the loader module 30 provided with a wafer transfer mechanism 40 to be described later, and a load port 32 on which a FOUP 31 capable of accommodating a plurality of wafers W is placed. Further, an orientation module (not shown) for adjusting a horizontal orientation of the wafer W, a storage module (not shown) for storing a plurality of wafers W, or the like may be disposed adjacent to the loader module 30.

The loader module 30 has a rectangular housing, and an inner space of the housing is maintained in an atmospheric atmosphere. A plurality of, e.g., five, load ports 32 are arranged side by side on one longitudinal side of the housing of the loader module 30. The load-lock modules 20 and 21 are arranged side by side on the other longitudinal side of the housing of the loader module 30.

The wafer transfer mechanism 40 for transferring the wafer W is disposed in the loader module 30. The wafer transfer mechanism 40 includes a transfer arm 41 that holds and moves the wafer W, a rotatable table 42 that rotatably supports the transfer arm 41, and a rotatable table base 43 on which the rotatable table 42 is placed. A guide rail 44 extending in the longitudinal direction of the loader module 30 is disposed in the loader module 30. The rotatable table base 43 is disposed on the guide rail 44, and the wafer transfer mechanism 40 is configured to be movable along the guide rail 44.

The depressurization unit 11 includes a transfer module 50 as a substrate transfer chamber for transferring the wafer W therein, and processing modules 60 for performing desired processing on the wafer W transferred from the transfer module 50. The inner atmospheres of the transfer module 50 and the processing module 60 are maintained in a depressurized atmosphere. In the present embodiment, a plurality of, e.g., eight processing modules 60 are connected to one transfer module 50. The number and the arrangement of the processing modules 60 are not limited to those described in the present embodiment, and may be set in any appropriate manners.

The transfer module 50 as a first chamber has a polygonal (pentagonal shape in the illustrated example) housing, and is connected to the load-lock modules 20 and 21 as described above. The transfer module 50 transfers the wafer W loaded into the load-lock module 20 to one of the processing modules 60. The wafer W is subjected to desired processing, and then unloaded to the atmospheric unit 10 through the load-lock module 21.

The processing module 60 as a second chamber performs plasma processing related to the post-treatment, such as asking or the like. As the processing module 60, any module that performs processing suitable for the purpose of wafer processing can be selected. The internal configuration of the processing module 60 is not particularly limited, and any configuration can be employed as long as desired plasma processing can be performed on the wafer W.

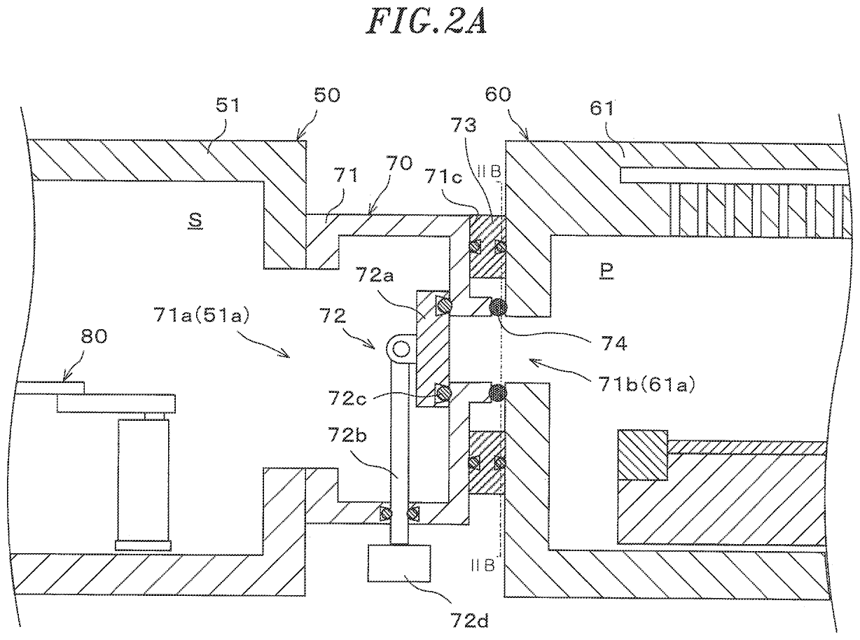

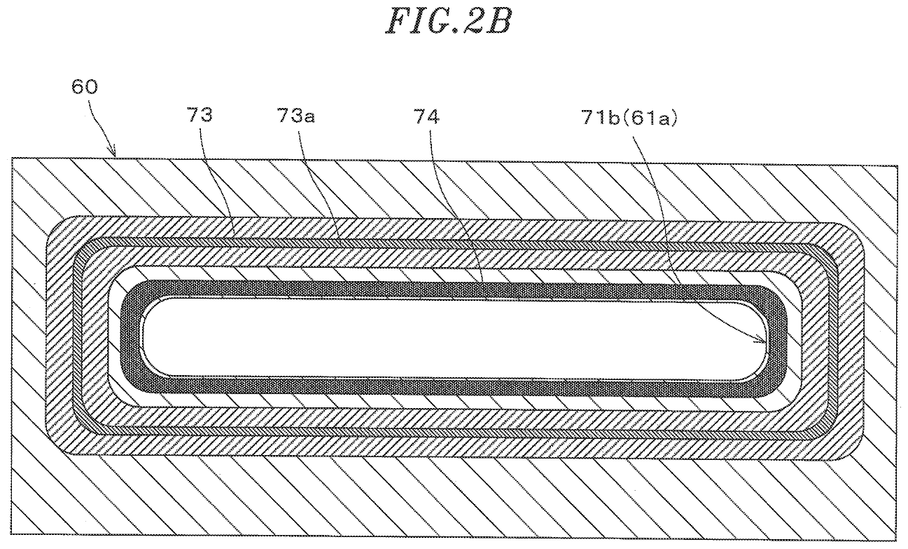

Further, the processing module 60 communicates with the transfer module 50 through a gate module 70. The gate module 70 is configured to connect openings 51a and 61a (see FIGS. 2A and 2B) with each other, which are respectively formed on wall surfaces of the transfer module 50 and the processing module 60 and serve as transfer ports (first substrate transfer port and second substrate transfer port) of the wafer W, and functions as a substrate transfer path between the transfer module 50 and the processing module 60.

The gate module 70 serving as a connecting member is configured to connect the inner space of the transfer module 50 (hereinafter, it may be referred to as “transfer space S”) and the inner space of the processing module 60 (hereinafter, it may be referred to as “processing space P”) through a gate valve 72 (see FIG. 2A) to be described later. The detailed configurations of the gate module 70 and the gate valve 72 will be described later.

A wafer transfer mechanism 80 for transferring the wafer W is disposed in the transfer module 50. The wafer transfer mechanism 80 includes a transfer arm 81 that holds and moves the wafer W, a rotatable table 82 that rotatably supports the transfer arm 81, and a rotatable table base 83 on which the rotatable table 82 is placed. A guide rail 84 extending in the longitudinal direction of the transfer module 50 is disposed in the transfer module 50. The rotatable table base 83 is disposed on the guide rail 84, and the wafer transfer mechanism 80 is configured to be movable along the guide rail 84.

In the transfer module 50, the transfer arm 81 receives the wafer W held by the load-lock module 20 and transfers the wafer W to one of the processing modules 60. The transfer arm 81 holds the wafer W that has been subjected to the desired processing in the processing module 60 and unloads same to the load-lock module 21.

The above-described wafer processing apparatus 1 includes a controller 90. The controller 90 is, e.g., a computer, and includes a program storage unit (not shown). A program for controlling wafer processing in the wafer processing apparatus 1 is stored in the program storage unit. The program storage unit also stores a program for controlling an operation of a driving system such as the transfer module 50, the processing module 60, or the like to implement the wafer processing in the wafer processing apparatus 1. The program may be recorded in a computer-readable storage medium H and may be retrieved from the storage medium H and installed on the controller 90.

While various embodiments have been described above, the present disclosure is not limited to the above-described embodiments, and various additions, omissions, substitutions and changes may be made. Further, other embodiments can be implemented by combining elements in different embodiments.

### <Wafer Processing Method>

The wafer processing apparatus 1 of the present embodiment is configured as described above. Next, wafer processing performed by the wafer processing apparatus 1 will be described.

First, the FOUP 31 containing a plurality of wafers W is placed on the load port 32, and the wafer W is taken out from the FOUP 31 by the wafer transfer mechanism 40. Next, the gate valve 22 of the load-lock module 20 is opened, and the wafer W is loaded into the load-lock module 20 by the wafer transfer mechanism 40.

After the gate valve 22 is closed to seal the load-lock module 20, the load-lock module 20 is depressurized to a desired vacuum level. When the load-lock module 20 is depressurized, the gate valve 23 is opened, and the inside of the load-lock module 20 and the inside of the transfer module 50 communicate with each other.

When the gate valve 23 is opened, the wafer W in the load-lock module 20 is transferred to the transfer module 50 by the wafer transfer mechanism 80, and the gate valve 23 is closed. Next, the gate valve 72 of one of the gate modules 70 is opened, and the wafer W is loaded into the corresponding processing module 60 by the wafer transfer mechanism 80. When the wafer W is loaded into the processing module 60, the gate valve 72 is closed to seal the processing module 60.

The processing module 60 performs any plasma processing suitable for the purpose of wafer processing, e.g., plasma processing related to post-treatment such as asking, or the like. Specifically, for example, after the wafer W is loaded, the processing module 60 is depressurized to a desired vacuum level. Then, a desired processing gas is supplied to the processing space P. Next, a radio frequency (RF) power for plasma generation is supplied by a power supply unit (not shown) in the processing module 60. Accordingly, the processing gas is excited, and plasma is generated. Then, the wafer W is subjected to desired plasma processing by the action of the generated plasma.

When the wafer W is subjected to the desired plasma processing, the gate valve 72 is opened, and the wafer W is unloaded from the processing module 60 by the wafer transfer mechanism 80. When the wafer W is unloaded from the processing module 60, the gate valve 72 is closed.

Next, the gate valve 23 of the load-lock module 21 is opened, and the wafer W is loaded into the load-lock module 21 by the wafer transfer mechanism 80. The gate valve 23 is closed to seal the load-lock module 21 and, then, the load-lock module 21 is opened to the atmosphere. When the load-lock module 21 is opened to the atmosphere, the gate valve 22 is opened, and the inside of the load-lock module 21 and the inside of the loader module 30 communicate with each other.

When the gate valve 22 is opened, the wafer W in the load-lock module 21 is transferred to the loader module 30 by the wafer transfer mechanism 40, and the gate valve 22 is closed. Then, the wafer W is returned to and accommodated in the FOUP 31 placed on the load port 32 by the wafer transfer mechanism 40. In this manner, a series of wafer processing in the wafer processing apparatus 1 is ended.

### <Gate Module>

In the above-described embodiment, when the plasma processing related to the post-treatment, such as the asking or the like, is performed in the processing module 60, the plasma processing may be performed under a high temperature environment (e.g., 100° C. or higher), and, thus, the processing module 60 may reach a high temperature. In such event, since the gate valve 72 is provided with an electrical component (e.g., an actuator or a positioning sensor) that is weak to the high temperature environment, for example, it is required to prevent the electrical component from reaching a high temperature.

In order to prevent the temperature of the electrical component from reaching a high temperature, the processing module 60 and the gate module 70 may be connected by using, as an adaptor, a heat shield plate (e.g., a resin material) for suppressing heat transfer as described above, for example. However, a high strength heat shield plate (resin material) that can be suitable to be used as the adapter is weak to deterioration caused by radicals. In other words, it is necessary to protect the heat shield plate from the radicals.

Therefore, in the following description, the configuration of the gate module 70 according to an embodiment, which can shield heat between the processing module 60 and the gate module 70 by using a heat shield member and also appropriately protect the heat shield member from radicals, will be described with reference to the drawings. FIG. 2A is a side cross-sectional view schematically showing the configuration of the gate module 70 according to the embodiment. FIG. 2B represents a front cross-section along the line IIB-IIB shown in FIG. 2A viewed from the transfer module 50 side.

As shown in FIG. 2A, the gate module 70 includes a gate chamber 71 that connects a transfer chamber 51 defining the transfer space S in the transfer module 50 and a processing chamber 61 defining the processing space P in the processing module 60. Openings 71a and 71b are formed on sidewalls of the gate chamber 71. The gate chamber 71 is disposed such that the transfer space S of the transfer module 50 and the processing space P of the processing module 60 communicate with each other through the above-described openings 51a and 61a by the openings 71a and 71b.

As shown in FIG. 2A, in the gate chamber 71, the opening 71a (opening 51a) is larger than the opening 71b (opening 61a). In other words, a diameter on the processing module 60 side is smaller than a diameter on the transfer module 50 side in cross-sectional view. In the following description, a portion of the gate chamber 71 that is located at a radially outer portion than the opening 71b, i.e., a small diameter portion of the gate chamber 71 may be referred to as “end portion 71c.”

The gate valve 72 is disposed in the gate module 70. The gate valve 72 has a valve body 72a for opening/closing the opening 71b formed on the side surface of the gate chamber 71 on the processing module 60 side, a valve body moving portion 72b for moving the valve body 72a, and a positioning sensor (not shown) for detecting a position of the valve body 72a. Further, the gate valve 72 is provided with a sealing member 72c (e.g., an O-ring) for ensuring airtightness between the processing module 60 and the gate module 70.

The surface of the valve body 72a on the opening 71b side is a closed surface having an area larger than that of the opening 71b. When the valve body 72a closes the opening 71b, the closed surface covers the opening 71b and its periphery.

The valve body moving portion 72b is provided with a driving mechanism 72d, and moves the valve body 72a between a closed position at which the opening 71b is closed and a retracting position retracted from the opening 71b. The current position of the valve body 72a is detected by, e.g., a positioning sensor (not shown). The configuration of the driving mechanism 72d is not particularly limited, and one or more mechanisms selected from an actuator, a link mechanism, a cam mechanism, an air cylinder, a motor, and the like can be used, for example.

Further, the gate module 70 according to the embodiment is provided with a heat shield ring 73 for suppressing heat transfer between the transfer module 50 and the processing module 60, and a radical blocking ring 74 for preventing deterioration of the heat shield ring 73 due to radicals. As shown in FIG. 2B, the radical blocking ring 74 and the heat shield ring 73 are disposed in that order from the inside (inner side) of the gate chamber 71 along the opening 61a in cross-sectional view.

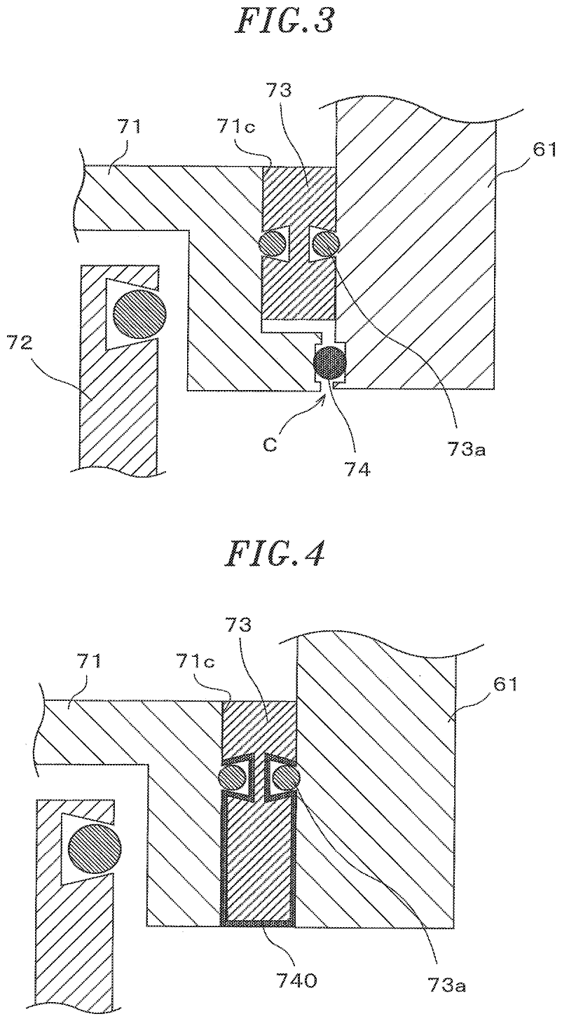

The heat shield ring 73 as the heat shield portion is disposed at the above-described end portion 71c, and connects the processing chamber 61 and the gate chamber 71 such that they are not in direct contact with each other as shown in FIG. 3. In other words, the processing chamber 61 and the gate chamber 71 are connected to each other through the heat shield ring 73. The heat shield ring 73 is made of an organic resin material having low thermal conductivity, e.g., engineering plastic (PI, PEEK, PEI, POM, nylon, PBI, PC, PMMA, ABS, or the like), to suppress heat transfer by way of thermally blocking the processing chamber 61 and the gate chamber 71. The thermal conductivity of the heat shield ring is preferably less than, e.g., 0.4 W/m·K to thereby appropriately suppress heat transfer between the processing chamber 61 and the gate chamber 71. Further, a sealing member 73a (e.g., an O-ring) is disposed between the heat shield ring 73 and the processing chamber 61 and between the heat shield ring 73 and the gate chamber 71.

The shape or the size of the heat shield ring 73 is not particularly limited as long as the processing chamber 61 and the gate chamber 71 can be connected to each other without being in direct contact with each other. However, in order to suppress the influence of radiant heat between the processing chamber 61 and the gate chamber 71, it is preferable to make as wide as possible the area of the wall surfaces of the processing chamber 61 and the gate chamber 71 covered by the heat shield ring 73, for example. In other words, it is preferable to increase the size of the heat shield ring 73 and reduce exposed portions of the wall surfaces of the processing chamber 61 and the gate chamber 71.

Further, the thickness of the heat shield ring 73 disposed between the processing chamber 61 and the gate chamber 71 is preferably 10 mm or more to ensure a heat shield property between the chambers and also the durability of the heat shield ring 73. When the thickness of the heat shield ring 73 is smaller than 10 mm, heat transfer between the processing chamber 61 and the gate chamber 71 may not be appropriately suppressed.

Further, the surface of the heat shield ring 73 may be subjected to processing (e.g., embossing or coating) for reducing the amount of heat conduction between the processing chamber 61 and the gate chamber 71. However, if a surface pressure of contact surfaces between the heat shield ring 73 and the processing chamber 61 and between the heat shield ring 73 and the gate chamber 71 increases excessively, the heat shield ring 73 is deformed by creep, and a gap is formed between the heat shield ring 73 and the sealing member 73a, which results in deterioration of airtightness. Therefore, it is necessary to control a machining level such that a total contact area between the heat shield ring 73 and the processing chamber 61 and between the heat shield ring 73 and the gate chamber 71 is not reduced excessively (to prevent excessive increase of the surface pressure).

The radical blocking ring 74, as a protective member and radical blocking portion, is disposed at an inner side of the heat shield ring 73 along the opening 71b to prevent radicals from acting on the heat shield ring 73. Specifically, as shown in FIG. 3, the radical blocking ring 74 is disposed at the inner side (on the opening 71b side) of the heat shield ring 73 (the end portion 71c), to close a clearance C formed to prevent heat transfer between the processing chamber 61 and the gate chamber 71. The radical blocking ring 74 is made of a material (hereinafter, may be referred to as “radical-resistant material”) having radical-resistant property and capable of blocking penetration of radicals to appropriately prevent the action of radicals on the heat shield ring 73. For example, the radical blocking ring 74 is made of a composite material in which a fluorine rubber ring is covered with a resin (e.g., Teflon (Registered Trademark)) tube.

The material forming the radical blocking ring 74 is not limited to the composite material, and may be any material as long as the action of radicals on the heat shield ring 73 can be prevented. In other words, for example, the material forming the radical blocking ring 74 may vary depending on a concentration level of radicals generated in the processing chamber 61, and perfluoroelastomer (FFKM) or Teflon (Registered Trademark) having a high radical-resistant property can be used instead of the above-described composite material.

The dimension of the clearance C (distance between the opposing wall surfaces of the processing chamber 61 and the gate chamber 71) where the radical blocking ring 74 is disposed is preferably 0.2 mm or more so as to suppress an increase in a temperature of the gate chamber 71 due to radiant heat and prevent the contact between the processing chamber 61 and the gate chamber 71 due to deformation caused by deterioration of the heat shield ring 73 by time.

### <Operation and Effect of the Gate Module According to the Embodiment>

The gate module 70 is configured as described above. In the wafer processing apparatus 1 according to the embodiment, the heat transfer from the processing chamber 61 heated by the plasma processing to the gate chamber 71 (more specifically, the gate valve 72) is suppressed by connecting the processing chamber 61 and the gate chamber 71 through the heat shield ring 73. Accordingly, it is possible to suppress an increase in the temperature of the electrical component disposed at the gate valve 72 that is weak to the high temperature environment. In other words, it is possible to appropriately suppress the damage to the electrical component during the plasma processing.

In other words, since the heat transfer between the processing chamber 61 and the gate chamber 71 can be suppressed, even when the plasma processing is performed in the processing module 60 under a high temperature environment, the opening 71b (the opening 61a) can be closed by applying the conventional gate valve 72 for a low temperature range (e.g., 80° C. or lower).

Further, since the heat transfer from the processing chamber 61 (the gate chamber 71) to the transfer chamber 51 is suppressed, the increase in the temperature of the transfer chamber 51 can be prevented. Accordingly, the increase in the temperature of the electrical component (e.g., the positioning sensor for the wafer W that is disposed at the wafer transfer mechanism 80) that is disposed in the transfer chamber 51 and weak to the high temperature environment is suppressed, and the damage to the electrical component can be appropriately suppressed.

Further, by providing the radical blocking ring 74 made of a radical-resistant material capable of blocking penetration of radicals at the inner side (on the processing space P side) of the heat shield ring 73, it is possible to prevent the penetration of radicals to the outer side (on the external space side) of the radical blocking ring 74. Accordingly, the penetration of radicals into the heat shield ring 73 can be suppressed, and the deterioration of the heat shield ring 73 by the radicals during plasma processing can be appropriately prevented.

Further, in accordance with the present embodiment, the dimension of the clearance C between the processing chamber 61 and the gate chamber 71 where the radical blocking ring 74 is disposed is designed to a dimension (e.g., 0.2 mm or more) that suppresses the heating of the gate chamber 71 by heat radiation and prevents the contact between the processing chamber 61 and the gate chamber 71 due to the deformation of the heat shield ring 73. Accordingly, it is possible to more appropriately suppress the heat transfer between the processing chamber 61 and the gate chamber 71, and also possible to more appropriately suppress an increase in the temperature of the electrical component weak to a high temperature environment.

In the above-described embodiment, the case where the deterioration of the heat shield ring 73 by radicals is prevented by providing the radical blocking ring 74 has been described as an example. However, the structure of the radical blocking portion for suppressing the action of the radicals on the heat shield ring 73 is not limited to thereto.

Specifically, for example, as shown in FIG. 4, a radical blocking layer 740, as the radical blocking portion, made of a radical-resistant material may be formed on the surface of the heat shield ring 73. The radical blocking layer 740 may be formed by attaching a radical-resistant material to the surface (at least an inner peripheral surface) of the heat shield ring 73 or by coating the surface (at least the inner peripheral surface) of the heat shield ring 73 with a radical-resistant material, for example. By forming the radical blocking layer 740 on the surface of the heat shield ring 73, the penetration of radicals into the heat shield ring 73 can be suppressed and the deterioration of the heat shield ring 73 due to radicals during plasma processing can be prevented as in the above-described embodiment.

In the case of forming the radical blocking layer 740, the radical blocking layer 740 suppresses the deterioration of the sealing member 73a due to radicals, and, therefore, it is preferable to form the radical blocking layer 740 on the surface of the heat shield ring 73 at least up to the installation position of the sealing member 73a.

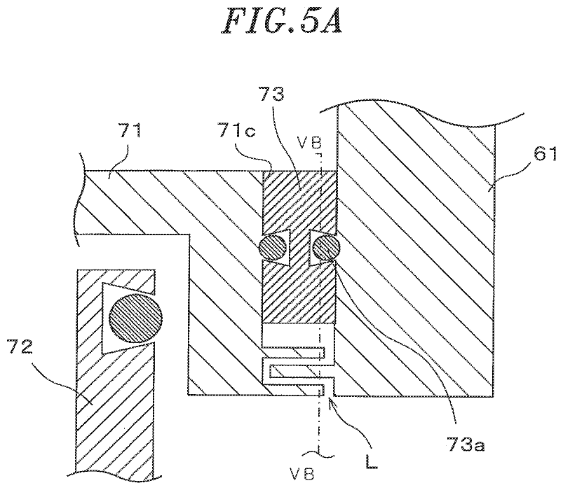

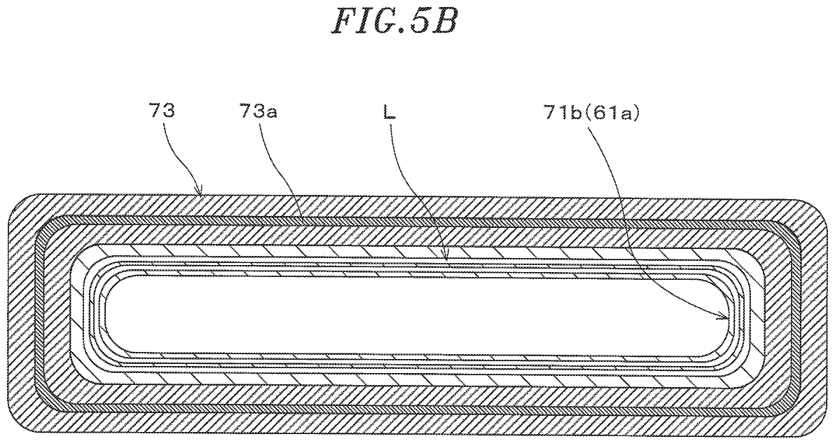

Further, the radical blocking unit may have a labyrinth structure L that can reduce the amount of radicals reaching the heat shield ring 73 by deactivating radicals. Specifically, as shown in FIGS. 5A and 5B, for example, convex portions protruding in an outer peripheral direction are respectively formed on the sidewalls of the processing chamber 61 and the gate chamber 71, and disposed in a non-contact manner at an inner side of the heat shield ring 73. In other words, an annular gap forming the labyrinth structure L having at least one folded portion is formed between the transfer module 50 and the gate module 70. Thus, a radical flow path curved to the inner side of the heat shield ring 73 is formed, and the amount of radicals reaching the heat shield ring 73 can be reduced by deactivating radicals. Hence, the deterioration of the heat shield ring 73 can be suppressed.

Further, the radical blocking unit may have a plurality of structures arbitrarily selected among the radical blocking ring 74, the radical blocking layer 740, and the labyrinth structure L.

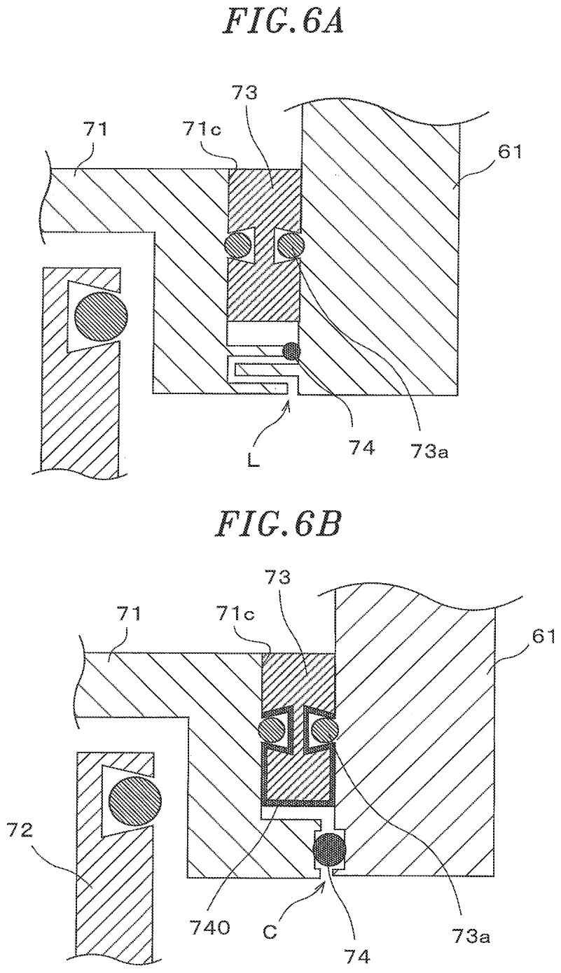

Specifically, for example, as shown in FIG. 6A, an annular gap forming the labyrinth structure L having at least one folded portion between the transfer module 50 and the gate module 70 may be formed on the inner side of the heat shield ring 73, and the radical blocking ring 74 as a second blocking layer may be formed at an outlet of the labyrinth structure L on the heat shield ring 73 side. Accordingly, the amount of radicals reaching the radical blocking ring 74 can be reduced, and the penetration of radicals into the heat shield ring 73 can be prevented more appropriately.

Further, for example, as shown in FIG. 6B, the radical blocking layer 740 as the second blocking layer may be formed on the surface of the heat shield ring 73, and the radical blocking ring 74 as the first blocking layer may be formed at the inner side of the heat shield ring 73.

In the above-described embodiment, the case where the transfer module 50 and the processing module 60 are connected through the gate module 70 as the connecting member has been described as an example. However, the position to which the connecting member related to the technique of the present disclosure is applied is not limited thereto. Specifically, the technique of the present disclosure can be applied even in the case where one processing module 60 as a first substrate processing chamber for performing plasma processing under a high temperature environment, and another processing module 60 as a second substrate processing chamber for performing plasma processing under a low temperature environment are connected, for example. In this case, the gate module 70 as the connecting member may be omitted.

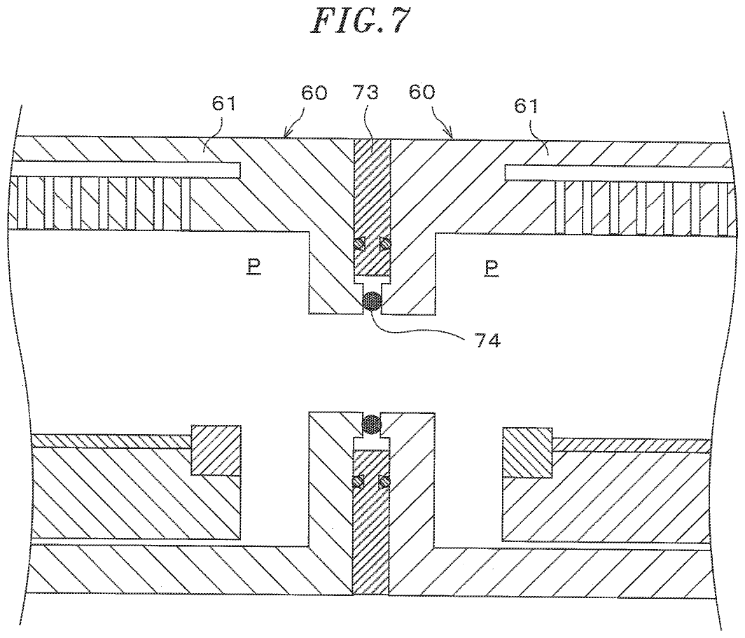

FIG. 7 schematically illustrates the configuration of the connecting member according to a second embodiment in the case where it is not necessary to block radicals between connected chambers, i.e., in the case where it is not necessary to provide the gate module 70 (the gate valve 72). As shown in FIG. 7, in the second embodiment, only the heat shield ring 73 and the radical blocking ring 74 are disposed between the processing chamber 61 of one processing module 60 and the processing chamber 61 of another processing module 60. In other words, in the present embodiment, the heat shield ring 73 and the radical blocking ring 74 constitute “the connecting member” of the present disclosure.

In accordance with the second embodiment, the heat transfer between one processing module 60 and another processing module 60 can be suppressed by connecting said one processing module 60 and said another processing module 60 through the heat shield ring 73. Accordingly, even when the processing temperature of the wafer W in one processing module 60 is different from that in another processing module 60, for example, the temperatures of the processing chambers 61 can be individually maintained, and the wafer processing in the processing chambers 61 can be appropriately performed.

Since the radical blocking ring 74 is disposed at the inner side of the heat shield ring 73 that connects the processing chambers 61, it is possible to appropriately prevent the heat shield ring 73 from being deteriorated by the radicals generated by the plasma processing performed in the plasma processing modules 60.

In the second embodiment, the case where each of the first substrate processing chamber and the second substrate processing chamber is the processing module 60 has been described as an example. However, the present embodiment can be applied even in the case where one of the first substrate processing chamber and the second substrate processing chamber is the transfer module 50.

In the first and second embodiments, as described above, the case where the plasma processing related to post-treatment, such as asking or the like, is performed in one processing module 60, i.e., the case where the heat shield ring 73 is protected from radicals has been described as an example. However, as described above, the technique of the present disclosure can be applied even when the wafer processing using a corrosive gas is performed under a high temperature environment in one processing module 60, for example. The wafer processing using a corrosive gas includes plasma processing such as etching, asking, or the like, and any other gas processing other than the plasma processing.

Specifically, for example, instead of or in addition to the radical blocking ring 74 shown in FIGS. 2A and 2B, a corrosive gas protective ring (not shown) as a corrosive gas blocking portion is disposed at an inner side of the heat shield ring 73 along the opening 71b, so that the deterioration of the heat shield ring 73 due to the corrosive gas is prevented. In this case, the corrosive gas protective ring functions as a “protective member” according to the technique of the present disclosure.

The corrosive gas protective ring can be made of any material selected depending on the type of the corrosive gas supplied into one processing module 60. For example, silicone rubber or Viton may be selected as a constituent material.

Similarly to the radical blocking ring 74, the corrosive gas protective ring may be made of, e.g., a radical-resistant material i.e., a high molecular (e.g., Teflon (Registered Trademark)) polymer. When the corrosive gas protective ring is made of the same material as that of the radical blocking ring 74, the heat shield ring 73 can be protected from both of the radicals and the corrosive gas.

For example, when the first blocking layer and the second blocking layer as the protective members are disposed at the inner side of the heat shield ring 73 as shown in FIG. 6, the first blocking layer and the second blocking layer may function as a radical blocking layer and a corrosive gas blocking layer, respectively.

As described above, in the technique of the present disclosure, even when the corrosive gas processing is performed on the wafer W under a high temperature environment in one processing module 60, the heat transfer from the processing chamber 61 to the gate chamber 71 can be appropriately suppressed, and the deterioration of the heat shield ring 73 due to the corrosive gas processing can be suppressed.

In the above-described embodiment, the case where the wafer processing apparatus 1 is a depressurization processing apparatus, i.e., the case where the processing module 60 performs plasma processing on the wafer W in a depressurized atmosphere, has been described as an example. However, the wafer processing apparatus 1 may be an atmospheric processing apparatus. In other words, the technique of the present embodiment can be applied even when the processing module 60 performs plasma processing on the wafer W under an atmospheric pressure atmosphere.

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A substrate processing system comprising:
a first chamber having a first substrate transfer port;
a second chamber having a second substrate transfer port and configured to perform substrate processing;
a connecting member that allows the first substrate transfer port and the second substrate transfer port to communicate with each other;
a heat shield portion disposed along the second transfer port in cross-sectional view and configured to thermally block the first chamber and the second chamber from each other; and
a protective member disposed between the heat shield portion and the second transfer port and configured to prevent deterioration of the heat shield portion during substrate processing in the second chamber.

2. The substrate processing system of claim 1, wherein the substrate processing is plasma processing, and
the protective member is configured to prevent penetration of radicals into the heat shield portion.

3. The substrate processing system of claim 2, wherein the protective member has a radical-resistant property and is formed in an annular shape.

4. The substrate processing system of claim 3, wherein the protective member includes a fluorine rubber ring and a resin tube that covers the fluorine rubber ring.

5. The substrate processing system of claim 1, wherein the protective member is a coating layer that has a radical-resistant property and covers a surface of the heat shield portion.

6. The substrate processing system of claim 1, wherein the substrate processing is gas processing using a corrosive gas, and
the protective member is configured to prevent deterioration of the heat shield portion due to the corrosive gas.

7. The substrate processing system of claim 6, wherein the protective member is made of at least one of silicone rubber, Viton, or a high molecular polymer.

8. The substrate processing system of claim 1, wherein the protective member is disposed to close a gap between the first chamber and the second chamber.

9. The substrate processing system of claim 8, wherein the gap is 0.2 mm or more.

10. The substrate processing system of claim 1, wherein the heat shield portion is made of a resin material selected from at least one of PI, PEEK, PEI, POM, nylon, PBI, PC, PMMA or ABS.

11. The substrate processing system of claim 10, wherein the resin material has thermal conductivity less than 0.4 W/m·K.

12. The substrate processing system of claim 1, wherein the heat shield portion has a thickness of 10 mm or more.

13. A substrate processing system comprising:
a first chamber having a first opening;
a second chamber having a second opening;
a connecting member that extends from the first chamber toward the second chamber and allows the first opening and the second opening to communicate with each other;
a first annular member fitted between the second chamber and the connecting member and made of an organic resin material having thermal conductivity less than 0.4 W/m·K; and
a second annular member fitted between the second chamber and the connecting member at an inner side of the first annular member and made of a radical-resistant material or a corrosion-resistant material.

14. The substrate processing system of claim 13, wherein the second annular member includes a main body made of a fluorine rubber material and the radical-resistant material that covers the main body.

15. The substrate processing system of claim 13, wherein the radical-resistant material is disposed on an inner peripheral surface of the first annular member.

16. The substrate processing system of claim 13, wherein the radical-resistant material is selected from a group comprising perfluoroelastomer (FFKM), Teflon, and combination thereof.

17. The substrate processing system of claim 13, wherein the corrosion-resistant material is selected from a group comprising silicon, Viton, a high molecular polymer, and combination thereof.

18. The substrate processing system of claim 13, wherein the organic resin material is selected from a group comprising PI, PEEK, PEI, POM, nylon, PBI, PC, PMMA, ABS, and combination thereof.

19. A substrate processing system comprising:
a first chamber having a first opening;
a second chamber having a second opening;
a connecting member that extends from the first chamber toward the second chamber and allows the first opening and the second opening to communicate with each other, wherein an annular gap is formed between the second chamber and the connecting member and defined by a labyrinth structure having at least one folded portion; and
an annular member fitted between the second chamber and the connecting member at an outer side of the annular gap and made of an organic resin material having thermal conductivity less than 0.4 W/m·K.

20. The substrate processing system of claim 19, further comprising:
an additional annular member disposed in the annular gap and made of a radical-resistant material or a corrosion-resistant material.
